(19) United States
(12) Patent Application Publication
(10) Pub. No.: US 2026/0221969 A1
(43) Pub. Date: Jul. 30, 2026

(54) SEMICONDUCTOR DEVICE AND SWITCHING CIRCUIT

(71) Applicants: ROHM CO., LTD., Kyoto (JP); Ancora Semiconductors Inc., Taoyuan City (TW)

(72) Inventors: Takumi FUJIMAKI, Kyoto (JP); Satoru NATE, Kyoto (JP); Ying-Chen LIU, Taoyuan City (TW); Wei-Hsiang CHAO, Taoyuan City (TW)

(21) Appl. No.: 19/457,643

(22) Filed: Jan. 23, 2026

(30) Foreign Application Priority Data
Jan. 29, 2025 (JP) 2025-012851

(51) Int. Cl. H03K 17/687

(52) U.S. Cl. CPC H03K 17/687

(57) ABSTRACT

A semiconductor device includes: a GaN power element configured to include a gate, a drain and a source; a drive circuit configured to drive the GaN power element; and a monitoring circuit configured to monitor a voltage between the drain and the source of the GaN power element. The drive circuit is configured to turn off the GaN power element based on an output of the monitoring circuit. The monitoring circuit includes a diode a cathode of which is connected to the drain of the GaN power element. The drive circuit is mounted on a Si chip. The GaN power element and the diode are mounted on a GaN chip.

### CROSS-REFERENCE TO RELATED APPLICATIONS

This nonprovisional application claims priority under 35 U.S.C. § 119(a) on Patent Application No. 2025-012851 filed in Japan on January 29, 2025, the entire contents of which are hereby incorporated by reference.

### BACKGROUND OF THE INVENTION

### 1. Technical Field

The present disclosure relates to semiconductor devices and switching circuits.

### 2. Description of Related Art

In recent years, semiconductor devices which include gallium nitride (GaN) power elements have been increasingly commercialized (see, for example, Japanese Unexamined Patent Application Publication No. 2024-70020).

### BRIEF DESCRIPTION OF THE DRAWINGS

FIG. 1 is a diagram showing the configuration of a semiconductor device according to a first embodiment;

FIG. 2 is a timing chart showing waveforms of voltages and currents at parts of the semiconductor device according to the first embodiment;

FIG. 3 is a perspective view of the appearance of the semiconductor device according to the first embodiment;

FIG. 4 is a diagram showing the configuration of a semiconductor device according to a second embodiment;

FIG. 5 is a diagram showing the configuration of a semiconductor device according to a third embodiment;

FIG. 6 is a timing chart showing waveforms of voltages at parts of the semiconductor device according to the third embodiment;

FIG. 7 is a diagram showing the configuration of a semiconductor device according to a fourth embodiment; and

FIG. 8 is a diagram showing a schematic configuration of a step-up DC/DC converter.

### DETAILED DESCRIPTION

In the present specification, a MOS (Metal Oxide Semiconductor) field effect transistor refers to a field effect transistor in which the structure of a gate includes at least three layers of “a layer formed of a conductor or a semiconductor such as polysilicon with a low resistance value”, “an insulating layer” and “a p-type, n-type or intrinsic semiconductor layer”. In other words, the structure of the gate of the MOS field effect transistor is not limited to a three-layer structure of metal, oxide and semiconductor.

In the present specification, a constant voltage means a voltage which is constant under ideal conditions, but actually refers to a voltage which may fluctuate slightly due to a temperature change or the like.

### First embodiment

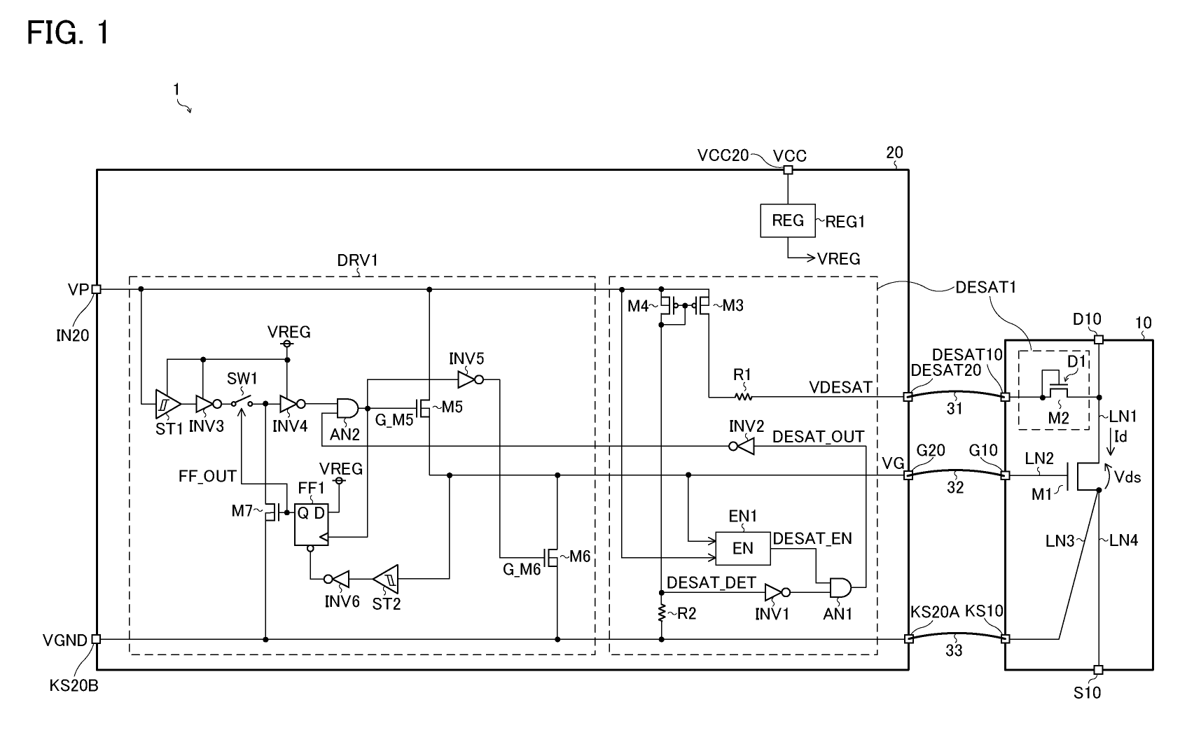

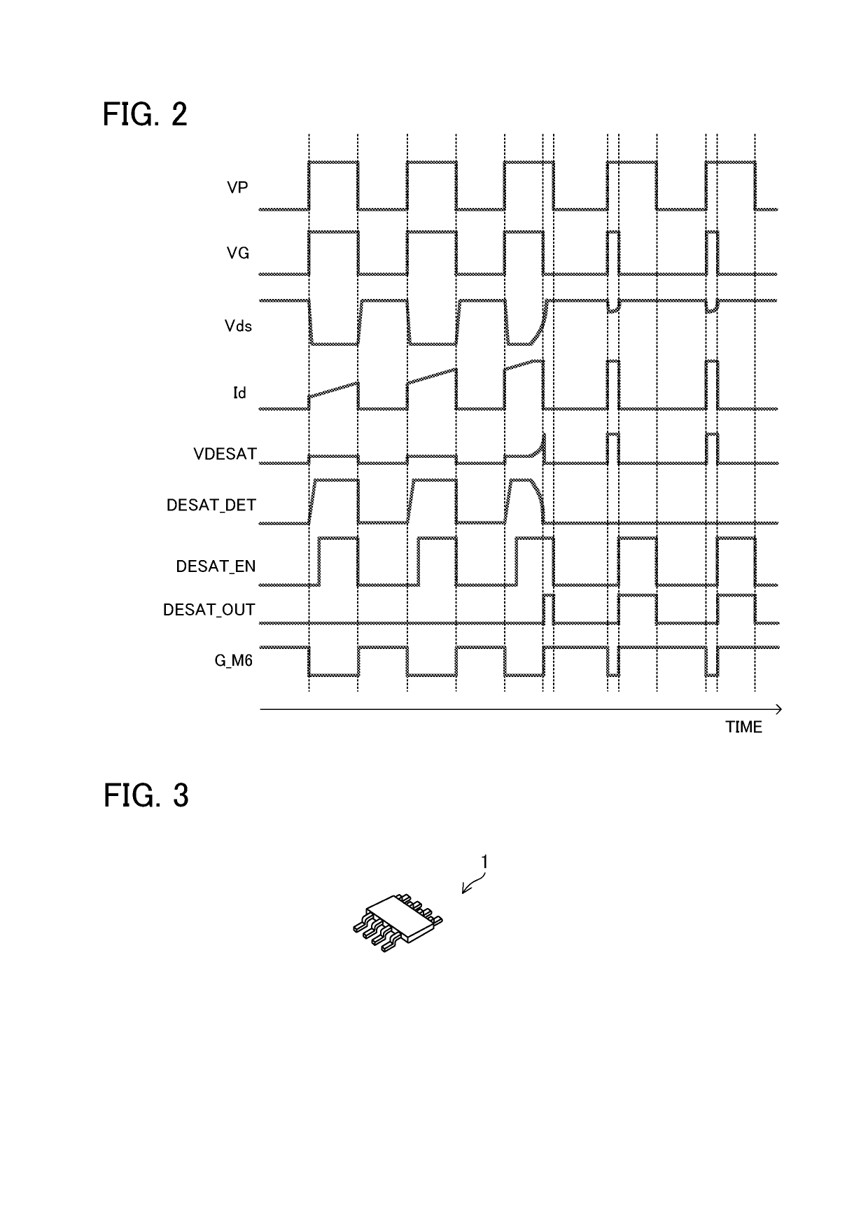

FIG. 1 is a diagram showing the configuration of a semiconductor device 1 according to a first embodiment. FIG. 2 is a timing chart showing waveforms of voltages and currents at parts of the semiconductor device 1. FIG. 3 is a perspective view of the appearance of the semiconductor device 1. The semiconductor device 1 is an electronic component formed by sealing a GaN chip 10 and a Si chip 20 which will be described later in a housing (package) made of resin. In the housing of a semiconductor device 1, a plurality of external terminals are provided to be exposed, and the external terminals include five external terminals which are electrically connected to pads D10, S10, IN20, KS20B and VCC20 shown in FIG. 1, respectively. The number of external terminals in the semiconductor device 1 shown in FIG. 3 and the appearance of the semiconductor device 1 are merely examples.

The semiconductor device 1 shown in FIG. 1 includes the GaN chip 10 and the Si chip 20. The GaN chip 10 is formed, for example, by cutting a GaN thin film formed on a silicon substrate or a sapphire substrate into chip shapes. The GaN chip 10 may be formed, for example, by cutting a GaN substrate into chip shapes. The Si chip 20 is formed, for example, by cutting a silicon substrate into chip shapes.

The GaN chip 10 includes a GaN power element M1, a diode D1, wires LN1 to LN4, a pad D10, a pad DESAT10, a pad G10, a pad KS10 and a pad S10.

The GaN power element M1 is, for example, a GaN high electron mobility transistor. The drain of the GaN power element M1 is electrically connected to the pad D10 via the wire LN1 in the GaN chip 10. The gate of the GaN power element M1 is electrically connected to the pad G10 via the wire LN2 in the GaN chip 10. The source of the GaN power element M1 is electrically connected to the pad KS10 via the wire LN3 in the GaN chip 10, and is electrically connected to the pad S10 via the wire LN4.

The anode of the diode D1 is electrically connected to the pad DESAT10. The cathode of the diode D1 is electrically connected to the drain of the GaN power element M1. The diode D1 is mounted on the GaN chip 10, and thus it is easy to increase the breakdown voltage of the diode D1 to the same level as the breakdown voltage of the GaN power element M1.

The diode D1 is, for example, a GaN high electron mobility transistor M2 which is diode-connected (in which the gate and the drain are short-circuited). Since a current flowing through the GaN high electron mobility transistor M2 is lower than a current flowing through the GaN power element M1, the size of the GaN high electron mobility transistor M2 can be reduced as compared with the size of the GaN power element M1. In terms of reducing the size and cost of the GaN chip 10, the size of the GaN high electron mobility transistor M2 is preferably smaller than the size of the GaN power element M1. Unlike the present embodiment, the diode D1 may be a PN junction diode.

The Si chip 20 includes a constant voltage source REG1, a driver DRV1, a part of a monitoring circuit DESAT1 excluding the diode D1, a pad IN20, a pad VCC20, a pad DESAT20, a pad G20, a pad KS20A and a pad KS20B.

The pad DESAT20 provided in the Si chip 20 is electrically connected to the pad DESAT10 provided in the GaN chip 10 by a bonding wire 31. The pad G20 provided in the Si chip 20 is electrically connected to the pad G10 provided in the GaN chip 10 by a bonding wire 32. The pad KS20A provided in the Si chip 20 is electrically connected to the pad KS10 provided in the GaN chip 10 by a bonding wire 33.

The constant voltage source REG1 generates a constant voltage VREG from a voltage VCC applied to the pad VCC20, and supplies the constant voltage VREG to parts in the Si chip 20.

Basically, when a pulse voltage VP applied to the pad IN20 is high, the driver DRV1 turns on an N-channel MOS field effect transistor M5 in the driver DRV1, turns off an N-channel MOS field effect transistor M6 in the driver DRV1 and thereby switches a drive voltage VG supplied to the pad G20 high (see FIG. 2).

However, when a voltage DESAT_OUT generated by the monitoring circuit DESAT1 is high, even if the pulse voltage VP applied to the pad IN20 is high, the driver DRV1 turns off the N-channel MOS field effect transistor M5 in the driver DRV1, turns on the N-channel MOS field effect transistor M6 in the driver DRV1 and thereby switches the drive voltage VG supplied to the pad G20 low (see FIG. 2). In other words, when the voltage DESAT_OUT generated by the monitoring circuit DESAT1 is high, the driver DRV1 turns off the GaN power element M1. In this way, since protection is provided when the GaN power element M1 is saturated, even if overcurrent protection is not provided, it is possible to prevent the GaN power element M1 from being destroyed. The protection which is performed by the semiconductor device 1 and is provided when the GaN power element M1 is saturated may be used together with the overcurrent protection for the drain current of the GaN power element M1, and may be performed in a state where the overcurrent protection for the drain current of the GaN power element M1 is not provided.

When the pulse voltage VP applied to the pad IN20 is low, a driver DRV1 turns off the N-channel MOS field effect transistor M5 in the driver DRV1, turns on the N-channel MOS field effect transistor M6 in the driver DRV1 and thereby switches the drive voltage VG supplied to the pad G20 low (see FIG. 2).

In the present embodiment, the description of details of the driver DRV1 is omitted.

The monitoring circuit DESAT1 includes the diode D1, a resistor R1, P-channel MOS field effect transistors M3 and M4, a resistor R2, an inverter (NOT gate) INV1, an enable circuit EN1, an AND gate AN1 and an inverter INV2.

The monitoring circuit DESAT1 monitors a voltage Vds between the drain and the source of the GaN power element M1.

When the GaN power element M1 is in an on state and is not saturated, since the voltage Vds between the drain and the source is lower than a voltage VDESAT supplied to the pad DESAT20, the P-channel MOS field effect transistor M3 which is a current source passes a current through the diode D1 via the resistor R1 which is a current-limiting resistor element.

By contrast, when the GaN power element M1 is in an on state and is saturated, since the voltage Vds between the drain and the source is higher than the voltage VDESAT supplied to the pad DESAT20, the P-channel MOS field effect transistor M3 serving as the current source does not pass a current through the diode D1.

The P-channel MOS field effect transistor M4 is a mirror current source which is configured to generate a mirror current corresponding to a current output from the P-channel MOS field effect transistor M3 serving as the current source.

The resistor R2 is a conversion element which is configured to convert the mirror current into a voltage DESAT_DET.

When the GaN power element M1 is in an on state and is not saturated, the voltage DESAT_DET is high. When the GaN power element M1 is in an on state and is saturated, the voltage DESAT_DET is low (the same level as a ground voltage VGND applied to the pad KS20B).

The enable circuit EN1 generates a voltage DESAT_EN which is an enable signal. When a certain time (for example, 100 nsec) has elapsed since the voltage VG was switched from low to high, the voltage DESAT_EN is switched from low to high. When the voltage VP is switched from high to low, the voltage DESAT_EN is switched from high to low. When the voltage DESAT_EN is high, a protection function when the GaN power element M1 is saturated is enabled whereas when the voltage DESAT_EN is low, the protection function when the GaN power element M1 is saturated is disenabled. The voltage DESAT_EN is used, and thus it is possible to suppress erroneous detection of the saturation of the GaN power element M1.

The voltage DESAT_OUT is generated by the logical product of the inverted signal of the voltage DESAT_DET and the voltage DESAT_EN. Then, the inverted signal of the voltage DESAT_OUT is supplied to the driver DRV1. When the inverted signal of the voltage DESAT_OUT is low, a voltage G_M5 which is supplied to the gate of the N-channel MOS field effect transistor M5 in the driver DRV1 is low, a voltage G_M6 which is supplied to the gate of the N-channel MOS field effect transistor M6 in the driver DRV1 is high and thus the drive voltage VG supplied to the pad G20 is low.

### Second embodiment

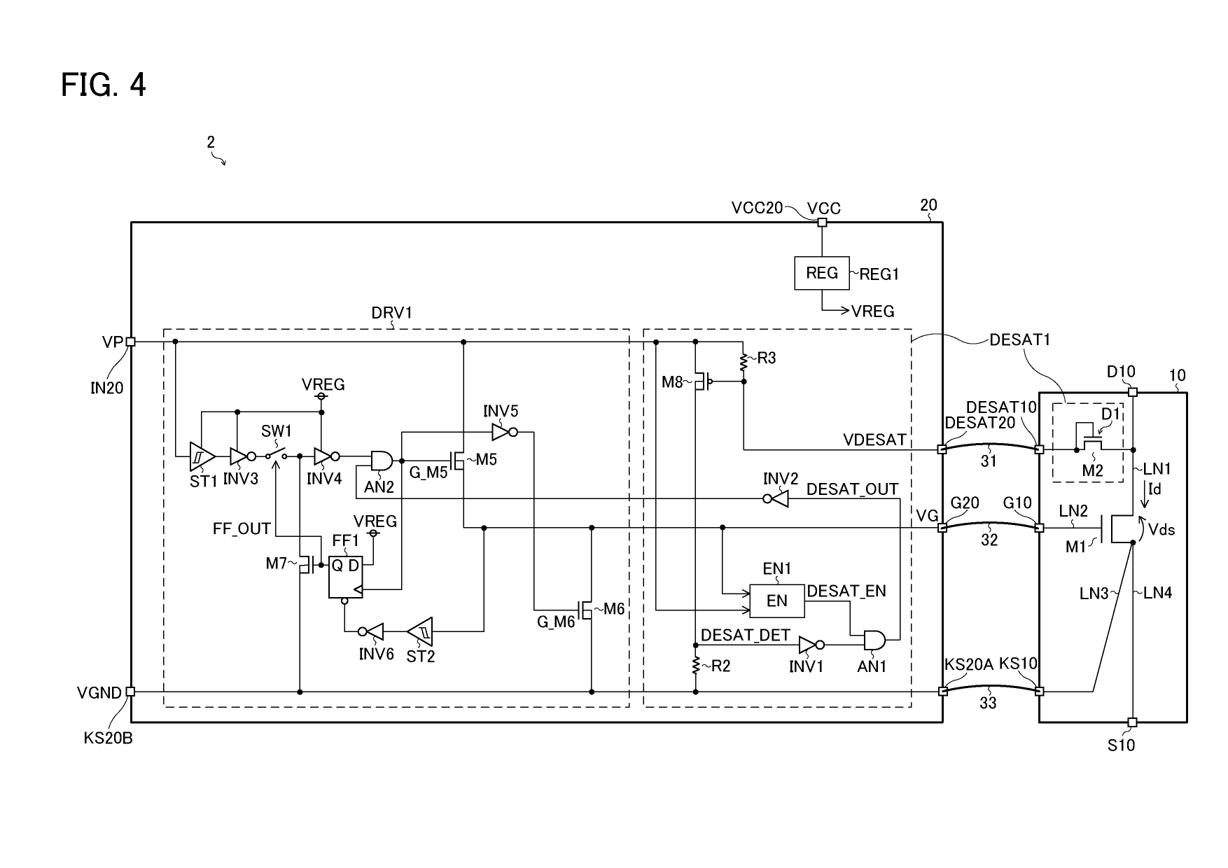

FIG. 4 is a diagram showing the configuration of the semiconductor device 2 according to a second embodiment. The semiconductor device 2 differs from the semiconductor device 1 in the configuration of a monitoring circuit DESAT1, and is basically the same as the semiconductor device 1 except the configuration of the monitoring circuit DESAT1.

The monitoring circuit DESAT1 in the present embodiment includes a resistor R3 and a P-channel MOS field effect transistor M8 instead of the P-channel MOS field effect transistors M3 and M4 and the resistor R1.

When the GaN power element M1 is in an on state and is not saturated, since the voltage Vds between the drain and the source is lower than the voltage VDESAT supplied to the pad DESAT20, the resistor R3 which is a current source passes a current through the diode D1. Here, a potential difference across the resistor R3 is higher than the threshold voltage of the P-channel MOS field effect transistor M8, and thus the P-channel MOS field effect transistor M8 is turned on. When the P-channel MOS field effect transistor M8 is turned on, a current flows through the resistor R2, and thus a potential difference occurs across the resistor R2, with the result that the voltage DESAT_DET is switched high.

By contrast, when the GaN power element M1 is in an on state and is saturated, since the voltage Vds between the drain and the source is higher than the voltage VDESAT supplied to the pad DESAT20, the resistor R3 serving as the current source does not pass a current through the diode D1. Here, since a potential difference does not occur across the resistor R3, a voltage between the gate and the source of the P-channel MOS field effect transistor M8 becomes zero, and thus the P-channel MOS field effect transistor M8 is turned off. When the P-channel MOS field effect transistor M8 is turned off, a current does not flow through the resistor R2, and thus a potential difference does not occur across the resistor R2, with the result that the voltage DESAT_DET is switched low (the same level as the ground voltage VGND applied to the pad KS20B).

### Third embodiment

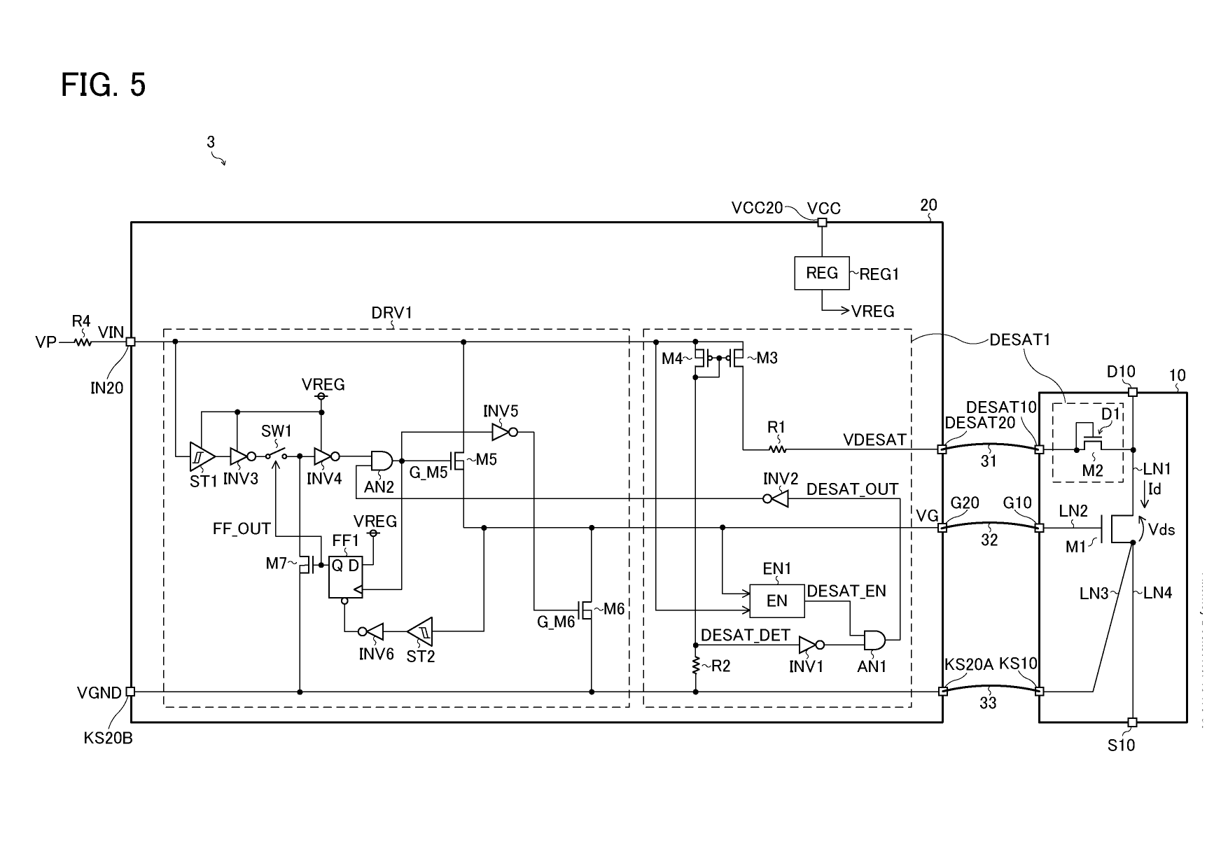

FIG. 5 is a diagram showing the configuration of a semiconductor device 3 according to a third embodiment. The semiconductor device 3 differs from the semiconductor device 1 in that a resistor R4 is added, and is basically the same as the semiconductor device 1 except that the resistor R4 is added.

The resistor R4 is disposed outside the Si chip 20 and the GaN chip 10.

The driver DRV1 includes a Schmitt trigger circuit ST1, inverters INV3 and INV4, an AND gate AN2, the N-channel MOS field effect transistor M5 which is a high-side switch, an inverter INV5 and the N-channel MOS field effect transistor M6 which is a low-side switch.

The driver DRV1 further includes a Schmitt trigger circuit ST2, an inverter INV6, a flip-flop FF1, a switch SW1 and an N-channel MOS field effect transistor M7.

In the following description, it is supposed that the GaN power element M1 is not saturated.

The current capability of the driver DRV1 when the N-channel MOS field effect transistor M5 is on is determined by the resistance value of the resistor R4. As the resistance value of resistor R4 is increased, a current flowing through the N-channel MOS field effect transistor M5 is decreased, and thus the slew rate of the voltage VG is decreased, with the result that EMI noise is reduced. In other words, the magnitude of the EMI noise when the N-channel MOS field effect transistor M5 is on can be adjusted by the resistor R4.

The N-channel MOS field effect transistor M6 has a current capability which can prevent self-turning of the GaN power element M1.

A voltage VIN applied to the pad IN20 is supplied to the input end of the Schmitt trigger circuit ST1. The voltage VIN is a voltage corresponding to the pulse voltage VP.

The voltage VIN is applied to the drain of the N-channel MOS field effect transistor M5, and switching control is performed on the N-channel MOS field effect transistors M5 and M6 based on the output of the Schmitt trigger circuit ST1. In this way, in a state where the N-channel MOS field effect transistor M5 is on, and the N-channel MOS field effect transistor M6 is off, the voltage VG is low, and thus the GaN power element M1 can be turned off.

Then, when the voltage VIN is lower than the first logic threshold value (for example, 1 V) of the Schmitt trigger circuit ST1, the N-channel MOS field effect transistor M6 is turned off. In the present embodiment, the first logic threshold value of the Schmitt trigger circuit ST1 is set lower than the plateau voltage of the GaN power element M1. Hence, in the present embodiment, since the GaN power element M1 is completely turned off, and then the N-channel MOS field effect transistor M6 is turned on, the N-channel MOS field effect transistor M6 having the current capability which can prevent self-turning of the GaN power element M1, that is, the high current capability can suppress an increase in the EMI noise.

In this way, the semiconductor device 3 can achieve both the adjustment of the EMI noise and the suppression of the self-turning on.

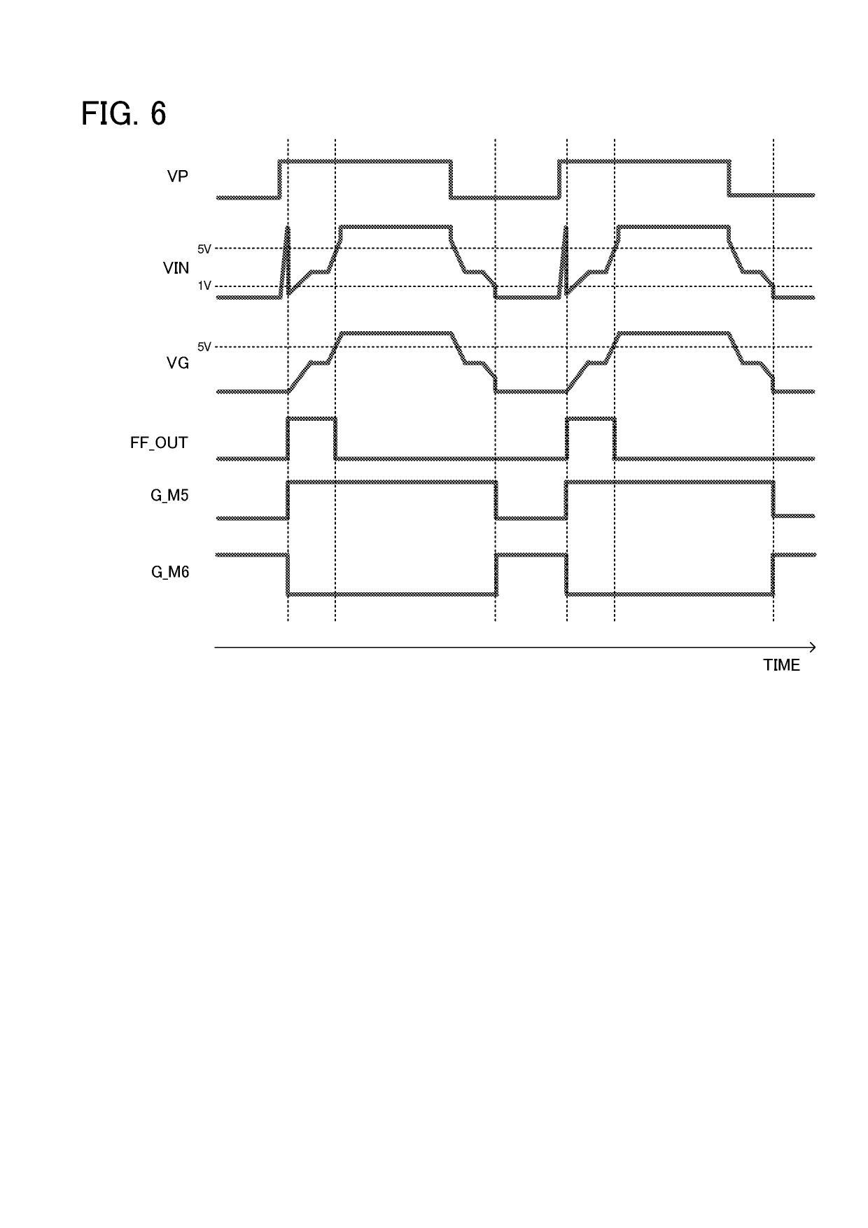

FIG. 6 is a timing chart showing waveforms of voltages at parts of the semiconductor device 3 according to the third embodiment. In a case where the resistance value of the resistor R4 is high, when the N-channel MOS field effect transistor M5 is switched from off to on, the voltage VP is divided by the resistor R4 and the on-resistance of the N-channel MOS field effect transistor M5 to increase the amount of drop in the voltage VIN, and thus the voltage VIN falls below the first logic threshold value of the Schmitt trigger circuit ST1, with the result that the switching control on the N-channel MOS field effect transistors M5 and M6 may be erroneously performed.

In order to cope with the erroneous performance described above, the driver DRV1 includes the flip-flop FF1 and the switch SW1. Until the voltage VG exceeds a second logic threshold value (for example, 5 V) after the voltage VIN exceeds the second logic threshold value of the Schmitt trigger circuit, the N-channel MOS field effect transistor M5 is held on, and the N-channel MOS field effect transistor M6 is held off. In order to realize the performance described above, the first logic threshold value of the Schmitt trigger circuit ST2 provided for resetting the flip-flop FF1 is set to the same value as the first logic threshold value of the Schmitt trigger circuit ST1, and the second logic threshold value of the Schmitt trigger circuit ST2 is set to the same value as the second logic threshold value of the Schmitt trigger circuit ST1.

### Fourth embodiment

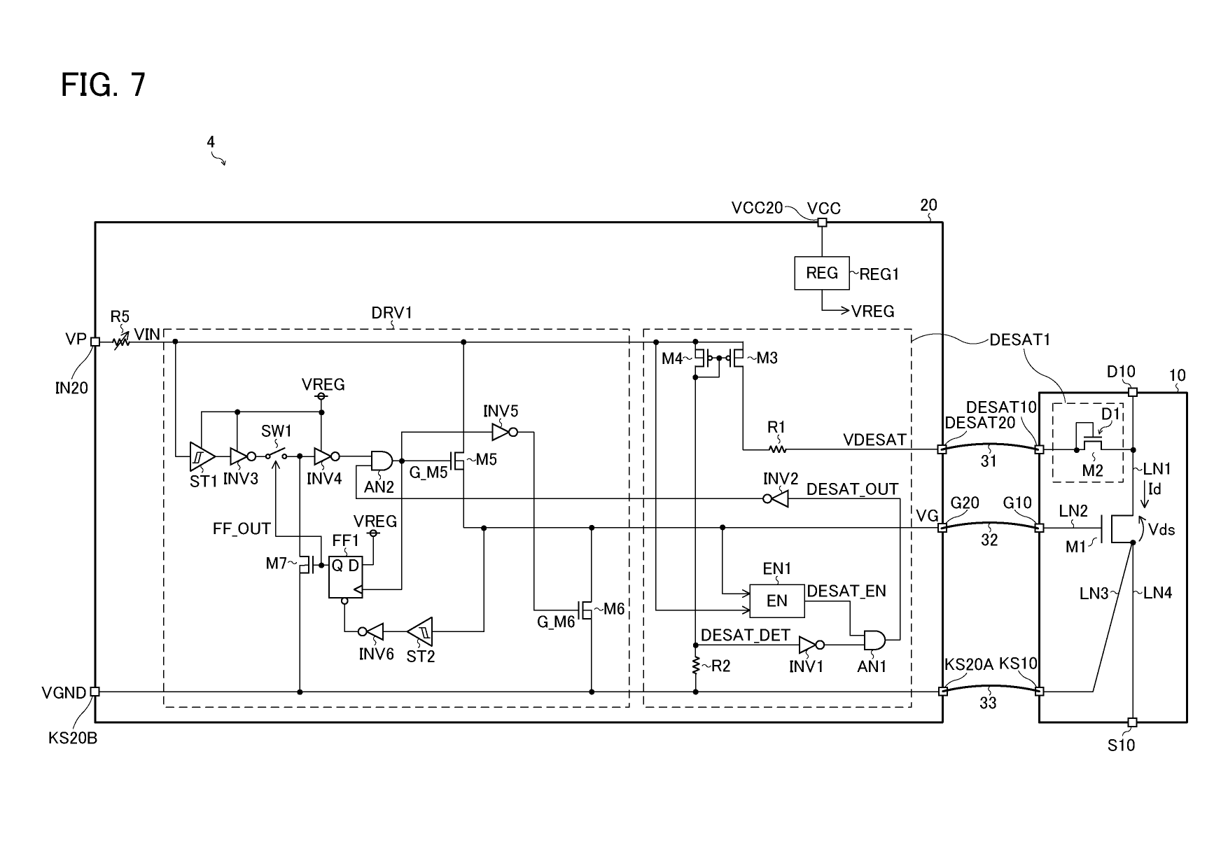

FIG. 7 is a diagram showing the configuration of a semiconductor device 4 according to a fourth embodiment. The semiconductor device 4 differs from the semiconductor device 3 in that a variable resistor R5 is provided instead of the resistor R4, and the variable resistor R5 is mounted on the Si chip 20, and is basically the same as the semiconductor device 3 except that the variable resistor R5 is provided instead of the resistor R4.

For example, in a circuit including a plurality of resistors and a plurality of switches, the on and off of each of the switches are switched, and thus the variable resistor R5 can adjust the resistance value.

### Application of switching circuit

Each of the semiconductor devices 1 to 4 described above is used as, for example, a part of a switching circuit. Examples of the switching circuit include a switching power supply circuit, a motor driver circuit and the like.

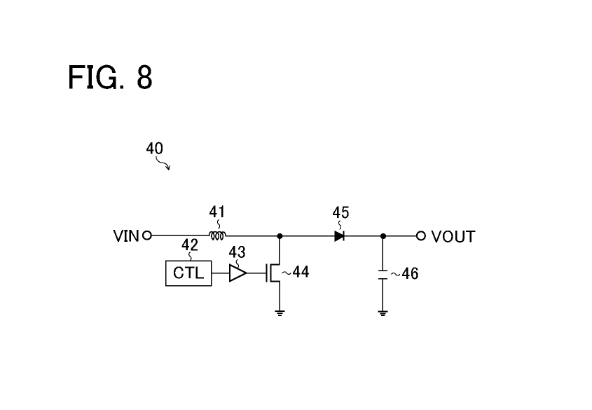

FIG. 8 is a diagram showing a schematic configuration of a step-up DC/DC converter which is an example of a switching power supply circuit. The step-up DC/DC converter 40 shown in FIG. 8 includes an inductor 41, a controller 42, a driver 43, a switching element 44, a diode 45 and a capacitor 46.

When the controller 42 turns on the switching element 44 via the driver 43, a current flows from the application end of an input voltage VIN through the inductor 41 to the switching element 44, and energy is stored in the inductor 41. When the controller 42 switches the switching element 44 from on to off via the driver 43, the energy stored in the inductor 41 is released, a current flows from the inductor 41 to the capacitor 46 through the diode 45 and the capacitor 46 is charged by an output voltage OUT which is higher than the input voltage VIN.

Each of the semiconductor devices 1 to 4 described above is used as the driver 43 and the switching element 44 in the step-up DC/DC converter 40 shown in FIG. 8.

### Others

It should be considered that the embodiments described above are illustrative in all respects, and not restrictive. The technical scope of the present disclosure is indicated not by the description of the above embodiments but by the scope of claims, and it should be understood that meanings equivalent to the scope of claims and all changes in the scope are included therein.

For example, in the third and fourth embodiments, the configuration may be changed such that the monitoring circuit DESAT1 is not provided. When the configuration is changed such that the monitoring circuit DESAT1 is not provided, the AND gate AN2 is removed from the driver DRV1, and the output end of the inverter INV4 is preferably connected to the gate of the P-channel MOS field effect transistor M5, the input end of the inverter INV5 and the clock input end of the flip-flop FF1.

### Additional remarks

Additional remarks are provided for the present disclosure the specific configuration examples of which are shown in the embodiments described above.

A semiconductor device (1, 2) in the present disclosure includes: a GaN power element (M1) configured to include a gate, a drain and a source; a drive circuit (DRV1) configured to drive the GaN power element; and a monitoring circuit (DESAT1) configured to monitor a voltage between the drain and the source of the GaN power element, the drive circuit is configured to turn off the GaN power element based on an output of the monitoring circuit, the monitoring circuit includes a diode (D1) a cathode of which is connected to the drain of the GaN power element, the drive circuit is mounted on a Si chip (20) and the GaN power element and the diode are mounted on a GaN chip (10) (first configuration).

In the semiconductor device of the first configuration, even if overcurrent protection is not provided when the GaN power element is saturated, it is possible to prevent the GaN power element from being destroyed.

In the semiconductor device of the first configuration, the drive circuit may include a current source (M3) configured to pass a current through the diode when the GaN power element is in an on state and is not saturated, and configured not to pass the current through the diode when the GaN power element is in the on state and is saturated (second configuration).

In the semiconductor device of the second configuration, the drive circuit may further include: a mirror current source (M4) configured to generate a mirror current corresponding to the current output from the current source; and a conversion element (R2) configured to convert the mirror current into a voltage (third configuration).

In the semiconductor device of the third configuration, the drive circuit may further include: a resistance element (R1) provided between the current source and the diode (fourth configuration).

In the semiconductor device of the second configuration, the drive circuit may further include: a switch (M8) configured to be turned on when the current source passes the current through the diode and turned off when the current source does not pass the current through the diode; and a first resistance element (R2) configured such that a potential difference occurs across the first resistance element when the switch is on, and the potential difference does not occur across the first resistance element when the switch is off (fifth configuration).

In the semiconductor device of the fifth configuration, the current source may be a second resistance element (R3) (sixth configuration).

In the semiconductor device of any one of the first to sixth configurations, the GaN power element may be a first GaN high electron mobility transistor, and the diode may be a second GaN high electron mobility transistor (M2) that is diode-connected (seventh configuration).

In the semiconductor device of the seventh configuration, the size of the second GaN high electron mobility transistor may be smaller than the size of the first GaN high electron mobility transistor (eighth configuration).

A switching circuit (40) in the present disclosure includes: the semiconductor device of any one of the first to eighth configurations (ninth configuration).

What is claimed is:

1. A semiconductor device comprising:
a GaN power element configured to include a gate, a drain and a source;
a drive circuit configured to drive the GaN power element; and
a monitoring circuit configured to monitor a voltage between the drain and the source of the GaN power element,
wherein the drive circuit is configured to turn off the GaN power element based on an output of the monitoring circuit,
the monitoring circuit includes a diode a cathode of which is connected to the drain of the GaN power element,
the drive circuit is mounted on a Si chip and
the GaN power element and the diode are mounted on a GaN chip.

2. The semiconductor device according to claim 1,
wherein the drive circuit includes a current source
configured to pass a current through the diode when the GaN power element is in an on state and is not saturated, and
configured not to pass the current through the diode when the GaN power element is in the on state and is saturated.

3. The semiconductor device according to claim 2,
wherein the drive circuit further includes:
a mirror current source configured to generate a mirror current corresponding to the current output from the current source; and
a conversion element configured to convert the mirror current into a voltage.

4. The semiconductor device according to claim 3,
wherein the drive circuit further includes a resistance element provided between the current source and the diode.

5. The semiconductor device according to claim 2,
wherein the drive circuit further includes:
a switch configured to be turned on when the current source passes the current through the diode and turned off when the current source does not pass the current through the diode; and
a first resistance element configured such that a potential difference occurs across the first resistance element when the switch is on, and the potential difference does not occur across the first resistance element when the switch is off.

6. The semiconductor device according to claim 5,
wherein the current source is a second resistance element.

7. The semiconductor device according to claim 1,
wherein the GaN power element is a first GaN high electron mobility transistor, and
the diode is a second GaN high electron mobility transistor that is diode-connected.

8. The semiconductor device according to claim 7,
wherein a size of the second GaN high electron mobility transistor is smaller than a size of the first GaN high electron mobility transistor.

9. A switching circuit comprising:
the semiconductor device according to claim 1.

10. A switching circuit comprising:
the semiconductor device according to claim 2.

11. A switching circuit comprising:
the semiconductor device according to claim 3.

12. A switching circuit comprising:
the semiconductor device according to claim 4.

13. A switching circuit comprising:
the semiconductor device according to claim 5.

14. A switching circuit comprising:
the semiconductor device according to claim 6.

15. A switching circuit comprising:
the semiconductor device according to claim 7.

16. A switching circuit comprising:
the semiconductor device according to claim 8.
